(19) United States
(12) Patent Application Publication
(10) Pub. No.: US 2004/0053452 A1
(43) Pub. Date: Mar. 18, 2004

(54) Method of fabricating semiconductor device

(75) Inventors: Isao Hasegawa, Gifu-shi (JP); Naoya Sotani, Mizuho-shi (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 10/659,346

(22) Filed: Sep. 11, 2003

(30) Foreign Application Priority Data
Sep. 18, 2002 (JP) JP2002-270936

(51) Int. Cl. H01L 21/00; H01L 21/324; H01L 21/477

(52) U.S. Cl. 438/151; 438/166; 438/795

(57) ABSTRACT

A method of fabricating a semiconductor device capable of inhibiting a silicon layer from agglomerating in a molten state without patterning the silicon layer is provided. This method of fabricating a semiconductor device comprises steps of forming a silicon layer to be in contact with at least either the upper surface or the lower surface of a first film having a contact angle of not more than about 45° with respect to molten silicon and crystallizing the silicon layer after melting the silicon layer by heating the silicon layer with a continuously oscillated electromagnetic wave.

### BACKGROUND OF THE INVENTION

1. Field of the Invention

The present invention relates to a method of fabricating a semiconductor device, and more specifically, it relates to a method of fabricating a semiconductor device including a step of crystallizing a silicon layer.

2. Description of the Background Art

A thin-film transistor (hereinafter referred to as a polycrystalline silicon TFT) employing a polycrystalline silicon film as an active layer has recently been employed as a pixel driving transistor for a liquid crystal display. In such a liquid crystal display, the performance of the polycrystalline silicon TFT must be improved in order to reduce the cost, improve the performance and render the liquid crystal display lightweight and compact. In order to improve the performance of the polycrystalline silicon TFT, a polycrystalline silicon film formed on a substrate must be converted to a single-crystalline state as much as possible.

A method of converting a polycrystalline silicon film to a single-crystalline state as much as possible through a continuous-wave laser beam is known in general. This is disclosed in AM-LCD '02, Digest of Technical Papers, July 10-12, 2002, pp. 227-230, for example.

According to this non-patent literature 1, the harmonic (532 nm) of a continuous-wave YVO₄ laser beam is directly applied to an amorphous silicon layer formed on a substrate through a silicon oxide film (SiO₂ film), thereby crystallizing the silicon layer.

In general, a silicon oxide film (SiO₂ film) is inferior in wettability with a layer of molten silicon due to a small contact angle with respect to molten silicon. Therefore, the layer of molten silicon inconveniently agglomerates into a bulk in crystallization. When a crystal growth method of moving the interface between a molten region and a crystal region of a silicon layer by scanning with a laser beam is employed, the molten region is also moved following movement of a heated region, leading a remarkable tendency toward agglomerating. According to the non-patent literature 1, the silicon layer formed on the silicon oxide film is previously patterned in the form of a ribbon thereby reducing the area of the molten silicon layer.

According to the non-patent literature 1, however, an element (TFT) must be formed on the region of the silicon layer patterned in the form of a ribbon as described above. Therefore, the area of the region for forming the element is disadvantageously reduced as compared with an unpatterned silicon layer. Further, the additional step of patterning the silicon layer disadvantageously results in reduction of the yield.

According to the non-patent literature 1, further, the laser output is small due to the harmonic (532 nm) of the YVO₄ laser beam employed for crystallizing the silicon layer. Consequently, it is disadvantageously difficult to improve productivity (throughput).

### SUMMARY OF THE INVENTION

An object of the present invention is to provide a method of fabricating a semiconductor device capable of inhibiting a silicon layer from agglomerating without patterning the silicon layer.

A method of fabricating a semiconductor device according to an aspect of the present invention comprises steps of forming a silicon layer to be in contact with at least either the upper surface or the lower surface of a first film having a contact angle of not more than about 45° with respect to molten silicon and crystallizing the silicon layer after melting the silicon layer by heating the silicon layer with a continuously oscillated electromagnetic wave.

In the method of fabricating a semiconductor device according to this aspect, as hereinabove described, the silicon layer is formed to be in contact with at least either the upper surface or the lower surface of the first film having the contact angle of not more than about 45° with respect to molten silicon and thereafter crystallized by melting, whereby the interfacial energy between the silicon layer and the first film is reduced when the silicon layer is molten due to the first film having a small contact angle with respect to molten silicon and hence wettability between the silicon layer and the first film can be improved. Thus, the silicon layer can be inhibited from aggregating in a molten state, to be inhibited from agglomerating in the molten state. Consequently, it is possible to inhibit the silicon layer from agglomerating while eliminating inconvenience resulting from patterning of the silicon layer.

In the method of fabricating a semiconductor device according to the aforementioned aspect, the first film preferably has a smaller contact angle with respect to molten silicon than a silicon oxide film. According to this structure, the silicon layer can be further inhibited from agglomerating as compared with a case of crystallizing the silicon layer while forming a silicon oxide film (SiO₂ film) to be in contact with either the upper or lower surface of the silicon layer.

In this case, the first film preferably includes at least either an SiNₓ film or an SiCN film having a contact angle of not more than about 45° with respect to molten silicon. According to this structure, the first film coming into contact with molten silicon exhibits a smaller contact angle with respect to molten silicon than a silicon oxide film, whereby the silicon layer can be more easily inhibited from agglomerating as compared with the case of crystallizing the silicon layer while forming a silicon oxide film (SiO₂ film) to be in contact with either the upper or lower surface of the silicon layer.

In this case, further, the first film preferably includes an SiC film. According to this structure, the silicon layer can be more easily inhibited from agglomerating as compared with the case of crystallizing the silicon layer while forming a silicon oxide film (SiO₂ film) to be in contact with either the upper or lower surface of the silicon layer due to the SiC film having a contact angle smaller than 45° with respect to molten silicon.

In the method of fabricating a semiconductor device according to the aforementioned aspect, the step of crystallizing the silicon layer preferably includes a step of forming an absorption film either above or under the silicon layer through an insulating layer, and a step of applying a continuous-wave laser beam to the absorption film thereby making the absorption film generate heat and crystallizing the silicon layer through generated the heat. According to this structure, the silicon layer can be crystallized with the continuous-wave laser beam having a large laser output not absorbed by the silicon layer, whereby productivity (throughput) can be improved. Further, the silicon layer is crystallized by indirect heating through the heat generated in the absorption film irradiated with the continuous-wave laser beam so that thermal dispersion can be relaxed before the absorption film radiates the heat toward the silicon layer also when the continuous-wave laser beam applied to the absorption film is dispersed to some extent. Thus, gigantic crystal grains or a gigantic single crystal can be formed without reducing the yield.

In this case, the continuous-wave laser beam preferably includes an infrared laser beam having a wavelength of at least about 0.75 μm and not more than about 2.0 μm. According to this structure, the absorption film can efficiently absorb the infrared laser beam hardly absorbed by the silicon layer. Thus, the absorption film can be efficiently heated.

In this case, further, the continuous-wave laser beam preferably includes a continuous-wave YAG laser beam. According to this structure, the absorption film can be easily efficiently heated.

In the aforementioned structure including the step of forming the absorption film, the absorption film preferably consists of a material including Mo. According to this structure, the absorption film can easily absorb the continuous-wave laser beam such as the continuous-wave YAG laser beam.

In the aforementioned structure including the step of forming the absorption film, the method of fabricating a semiconductor device preferably further comprises a step of forming a gate electrode by patterning the absorption film after the step of forming the absorption film. According to this structure, the absorption film can also be employed as the gate electrode, whereby steps of removing the absorption film and newly forming a gate electrode can be omitted. Thus, the fabrication process can be simplified.

In the aforementioned structure including the step of forming the absorption film, the step of forming the absorption film preferably includes a step of previously patterning the absorption film to be employable as a light-shielding film for a pixel part of a display. According to this structure, the absorption film can also be employed as the light-shielding film, whereby no light-shielding film may be separately formed. Consequently, the fabrication process can be simplified.

In this case, the step of previously patterning the absorption film to be employable as a light-shielding film for a pixel part of a display preferably includes a step of patterning the absorption film in the form of a matrix. According to this structure, the absorption film can be easily formed in a structure employable as a light-shielding film for a pixel part of a display.

In the method of fabricating a semiconductor device according to the aforementioned aspect, the step of crystallizing the silicon layer preferably includes a step of heating the silicon layer with a fundamental wave of the continuous-wave laser beam. According to this structure, it is possible to more efficiently heat the silicon layer with the fundamental wave having a larger laser output than a harmonic, thereby further prompting crystallization of the silicon layer. Thus, the productivity (throughput) can be further improved.

In the method of fabricating a semiconductor device according to the aforementioned aspect, the step of forming the silicon layer preferably includes a step of forming the silicon layer to be in contact with the upper surface of the first film, and the method of fabricating a semiconductor device preferably further comprises a step of forming the first film on a substrate through a buffer layer for relaxing heat transfer to the substrate in advance of formation of the silicon layer. According to this structure, it is possible to inhibit the substrate from cracking or distortion resulting from a thermal shock with the buffer layer while inhibiting the silicon layer from agglomerating with the first film. In this case, the buffer layer may include a silicon oxide film.

The method of fabricating a semiconductor device according to the aforementioned aspect preferably further comprises steps of forming a source/drain region on the silicon layer by implanting an impurity into the silicon layer and activating the impurity in the source/drain region with the continuously oscillated electromagnetic wave. According to this structure, it is possible to form a silicon TFT comprising the silicon layer having the source/drain region while inhibiting the silicon layer from agglomerating with the first film.

In this case, the method of fabricating a semiconductor device preferably further includes a step of forming a patterned gate electrode on the silicon layer in advance of the step of forming the source/drain region on the silicon layer. According to this structure, it is possible to easily form the source/drain region on the silicon layer by implanting the impurity into the silicon layer through a mask of the patterned gate electrode.

In this case, further, the method of fabricating a semiconductor device preferably further includes a step of applying a bias voltage between either the source or drain region of the silicon layer and the absorption film. According to this structure, the absorption film serves as a substrate bias plate, whereby the threshold voltage of a silicon TFT can be adjusted.

The method of fabricating a semiconductor device according to the aforementioned aspect preferably further comprises a step of forming roughness on the surface of the first film to be formed with the silicon layer in advance of the step of forming the silicon layer. According to this structure, it is possible to further reduce the contact angle of the first film with respect to molten silicon due to the roughness of the surface of the first film formed with the silicon layer. Thus, the silicon layer can be further inhibited from agglomerating.

In this case, the step of forming the roughness preferably includes a step of forming the roughness on the surface of the first film by etching the surface of the first film. According to this structure, roughness can be easily formed on the surface of the first film.

In the method of fabricating a semiconductor device according to the aforementioned aspect, the first film having the contact angle of not more than about 45° with respect to molten silicon may be an SiNₓ film formed by plasma CVD. In this case, the SiNₓ film is preferably formed by plasma CVD while setting the flow ratios of SiH₄ gas, NH₃ gas and N₂ gas to 2:1:100 to 2:2:100. At such flow ratios, the SiNₓ film can be easily formed by plasma CVD with the contact angle of not more than about 45° with respect to molten silicon.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view for illustrating a process of fabricating a semiconductor device according to a first embodiment of the present invention;

FIG. 2 is a plan view illustrating a step of forming an absorption film shown in FIG. 1;

FIGS. 3 to 5 are sectional views for illustrating the process of fabricating a semiconductor device according to the first embodiment;

FIG. 6 is a sectional view showing a structure prepared according to the method according to the first embodiment for experiments made for confirming effects of the present invention;

FIG. 7 is a sectional view showing a structure prepared according to a comparative method for the experiments made for confirming the effects of the present invention;

FIG. 8 schematically illustrates the relation between laser outputs and crystallized states in the structures prepared according to the methods shown in FIGS. 6 and 7;

FIG. 9 is a sectional view showing the surface structure of a sample causing disappearance of a film structure due to agglomerating of molten silicon;

FIG. 10 illustrates distribution of contact angles with respect to molten silicon in the structures according to the first embodiment and the comparative method shown in FIGS. 6 and 7 respectively;

FIG. 11 is a model diagram showing surface tension acting on molten silicon on an SiNₓ film;

FIG. 12 is a sectional view showing the surface structure of a sample prepared by forming roughness on the surface of an SiNₓ film;

FIG. 13 illustrates the relation between contact angles of SiNₓ films having a flat surface and an irregular surface respectively with respect to molten silicon; and

FIGS. 14 and 15 are sectional views for illustrating a process of fabricating a semiconductor device according to a second embodiment of the present invention.

### DESCRIPTION OF THE PREFERRED EMBODIMENTS

Embodiments of the present invention are now described with reference to the drawings.

(First Embodiment)

A method of fabricating a semiconductor device according to a first embodiment of the present invention is described with reference to FIGS. 1 to 13.

As shown in FIG. 1, an SiO₂ film (silicon oxide film) 2 is formed on a glass substrate 1 by low-pressure CVD with a thickness of about 300 nm. This silicon oxide film 2 serves as a buffer layer for relaxing heat transfer to the glass substrate 1. Thereafter an absorption film 3 of Mo is formed on a prescribed region of the silicon oxide film 2 by sputtering with a thickness of about 50 nm.

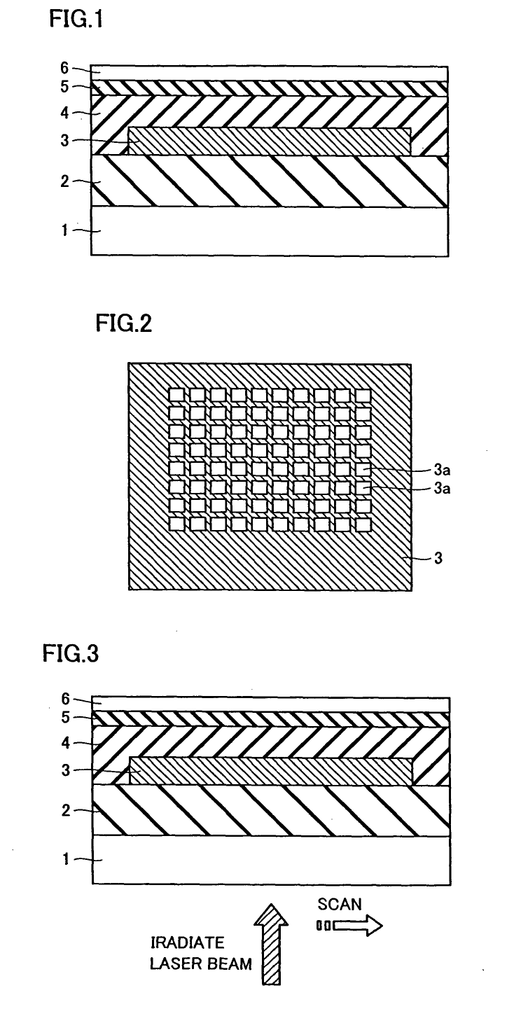

The absorption film 3 is patterned with holes 3a in the form of a matrix as shown in FIG. 2, to be employable as a black matrix (light-shielding film) of a pixel part of a liquid crystal display or an organic EL display later.

Referring again to FIG. 1, another silicon oxide film (SiO₂ film) 4 is formed by plasma CVD to cover the absorption film 3 with a thickness of about 80 nm.

According to the first embodiment, an SiNₓ film (silicon nitride film) 5 is thereafter formed on the silicon oxide film 4 by plasma CVD with a thickness of about 20 nm. The SiNₓ film 5 has a contact angle of not more than 45°, smaller than that of the SiO₂ film 4, with respect to molten silicon. The SiNₓ film 5 is an example of the “first film” in the present invention. Thereafter an amorphous silicon film 6 is formed on the SiNₓ film 5 by low-pressure CVD with a thickness of about 50 nm. The amorphous silicon film 6 is an example of the “silicon layer” in the present invention.

As shown in FIG. 3, a fundamental wave of a continuous-wave YAG laser beam is applied from the rear surface of the glass substrate 1 thereby crystallizing the amorphous silicon film 6 and obtaining a crystallized silicon film 6a. In this case, the laser beam is applied with an output of about 375 W and at a scanning rate of about 1 m/s.

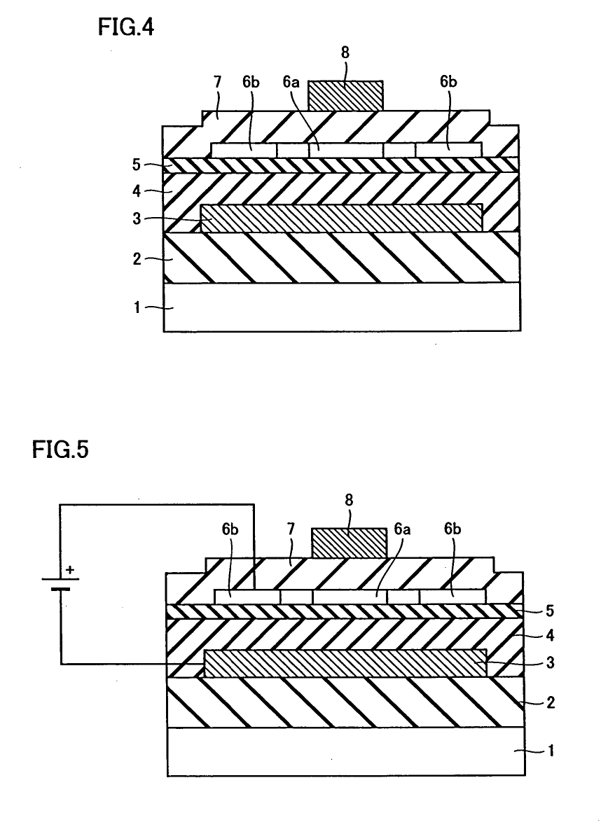

As shown in FIG. 4, a gate insulator film 7 consisting of a silicon oxide film (SiO₂ film) is formed to cover the crystallized silicon film 6a. A patterned gate electrode 8 of Mo or the like is formed on a prescribed region of the gate insulator film 7. An impurity is implanted into the crystallized silicon film 6a through a mask of the gate electrode 8 thereby forming a pair of source/drain regions 6b having an LDD structure. The crystallized silicon film 6a may be subjected to channel doping in advance of formation of the gate electrode 8 if necessary. In order to activate the implanted impurity, the continuous-wave YAG laser beam is applied similarly to the case of crystallization. Thus, a polycrystalline silicon TFT consisting of the pair of source/drain regions 6b, the gate insulator film 7 and the gate electrode 8 is formed according to the first embodiment.

According to the first embodiment, a bias voltage is applied between the absorption film 3 and either source/drain region 6b constituting a power supply line positioned on the drain side of the TFT. Thus, the absorption film 3 serves as a substrate bias plate, so that the threshold voltage Vₜₕ of the TFT can be adjusted.

According to the first embodiment, as hereinabove described, the amorphous silicon film 6 is formed to be in contact with the upper surface of the SiNₓ film (silicon nitride film) 5 having the contact angle of not more than 45° with respect to molten silicon and thereafter crystallized by melting so that the interfacial energy between molten silicon and the SiNₓ film 5 is reduced when the amorphous silicon film 6 is molten due to the SiNₓ film 5 having the small contact angle with respect to molten silicon, whereby wettability between molten silicon and the SiNₓ film 5 can be improved. Thus, it is possible to inhibit the amorphous silicon film 6 from aggregating in a molten state without patterning the same dissimilarly to the prior art, thereby inhibiting the amorphous silicon film 6 from agglomerating in the molten state. Consequently, it is possible to inhibit the amorphous silicon film 6 from agglomerating while preventing inconvenience such as reduction of the yield resulting from patterning of the amorphous silicon film 6.

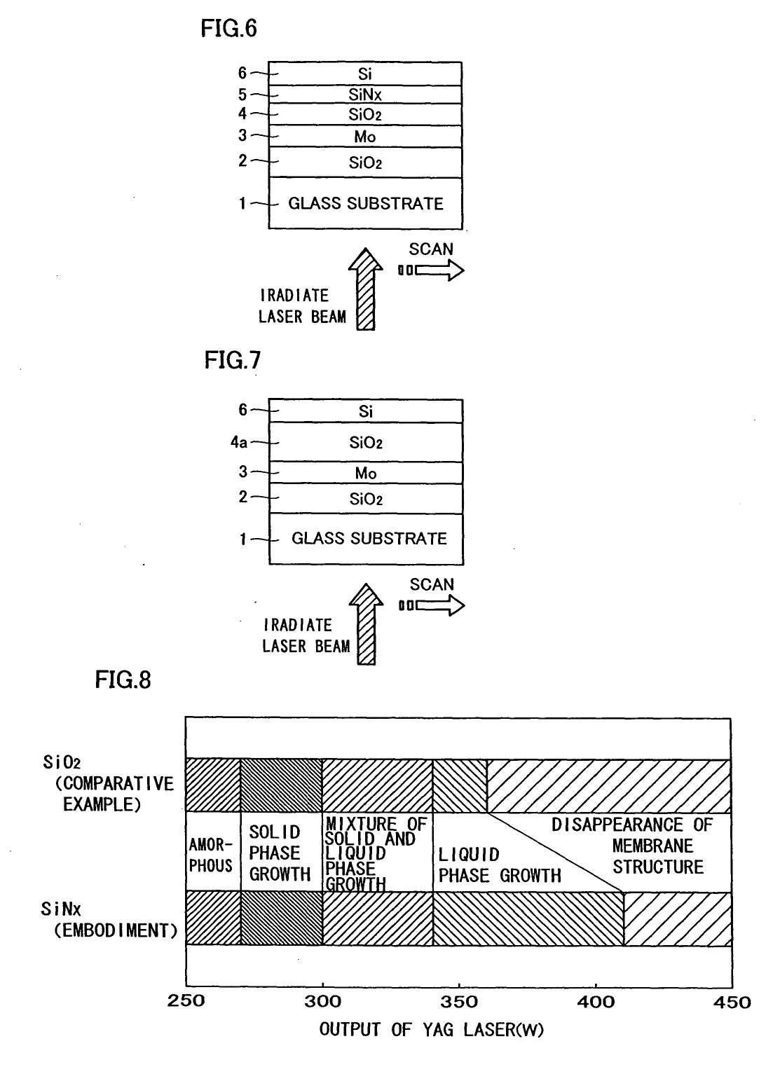

An experiment made for confirming the effect of an SiNₓ film having a contact angle of not more than 45° with respect to molten silicon formed to be in contact with the lower surface of an amorphous silicon film is described with reference to FIGS. 6 to 8. FIG. 6 illustrates a structure prepared according to the method of the first embodiment employed for this experiment, and FIG. 7 illustrates a structure prepared according to a comparative method employed for this experiment. In the structure prepared according to the method of the first embodiment shown in FIG. 6, an SiO₂ film 2 was formed on a glass substrate 1 by low-pressure CVD with a thickness of 300 nm, and an absorption film 3 of Mo was thereafter formed on the SiO₂ film 2 by sputtering with a thickness of 50 nm. Another SiO₂ film 4 having a thickness of 80 nm and an SiNₓ film 5 having a thickness of 20 nm were successively formed on the absorption film 3 by plasma CVD. Thereafter an amorphous silicon film 6 was formed on the SiNₓ film 5 by low-pressure CVD with a thickness of 50 nm.

In the structure prepared according to the comparative method shown in FIG. 7, an SiO₂ film 2 was formed on a glass substrate 1 by low-pressure CVD with a thickness of 300 nm, and an absorption film 3 of Mo was thereafter formed on the SiO₂ film 2 by sputtering with a thickness of 50 nm. Another SiO₂ film 4a having a thickness of 100 nm was formed on the absorption film 3 by plasma CVD, and an amorphous silicon film 6 was formed on the SiO₂ film 4a by low-pressure CVD with a thickness of 50 nm.

The structures shown in FIGS. 6 and 7 prepared in the aforementioned manner were irradiated with continuous-wave YAG laser beams at a scanning rate of 1 m/s while varying the laser outputs in the range of 250 W to 450 W, for confirming states of crystallization. FIG. 8 shows the results. More specifically, both of the structures according to the first embodiment and the comparative method exhibited amorphous crystal states when the laser outputs were not more than 270 W while exhibiting solid phase growth states when the laser outputs were between 270 W and 300 W. Further, both of the structures according to the first embodiment and the comparative method exhibited crystal states containing molten silicon and unmolten silicon in a mixed manner when the laser outputs were between 300 W and 340 W. When the laser outputs exceeded levels allowing liquid phase growth, film structures disappeared due to agglomerating. In this case, crystallization can be excellently performed in a region allowing liquid phase growth.

It is understood from FIG. 8 that laser outputs allowing liquid phase growth are in the narrow range of 340 W to 360 W (350 W±3%) in the structure according to the comparative method having the amorphous silicon film 6 formed on the SiO₂ film 4a. In the structure according to the first embodiment having the amorphous silicon film 6 formed on the SiNₓ film 5, on the other hand, laser outputs allowing liquid phase growth are in the range of 340 W to 410 W (375W±9%), and it is understood that the range of the laser outputs allowing liquid phase growth is enlarged as compared with the structure according to the comparative method. Thus, it has been proved possible to enlarge a process margin in the fabrication process according to the first embodiment. It is also understood from FIG. 8 that the film structure more hardly disappears in the structure according to the first embodiment as compared with the structure according to the comparative method also when irradiated with a YAG laser beam having a larger output. In other words, it has been proved that molten silicon is more hardly bulked (more hardly agglomerates) in the structure according to the first embodiment as compared with the structure according to the comparative method.

It has been proved by measuring oscillation stability of the laser output of a laser device that the laser output fluctuates (is dispersed) in the range of ±4%. Thus, a process condition allowing liquid phase growth in a range larger than that of ±4% with respect to a set value of the laser output is necessary for stably performing liquid phase growth. In consideration of this point, the method according to the first embodiment allowing liquid phase growth in the range of 375 W±9% as described above has a process condition wider than output fluctuation of the laser device. Consequently, it has been proved possible to stably crystallize the amorphous silicon film 6 according to the first embodiment.

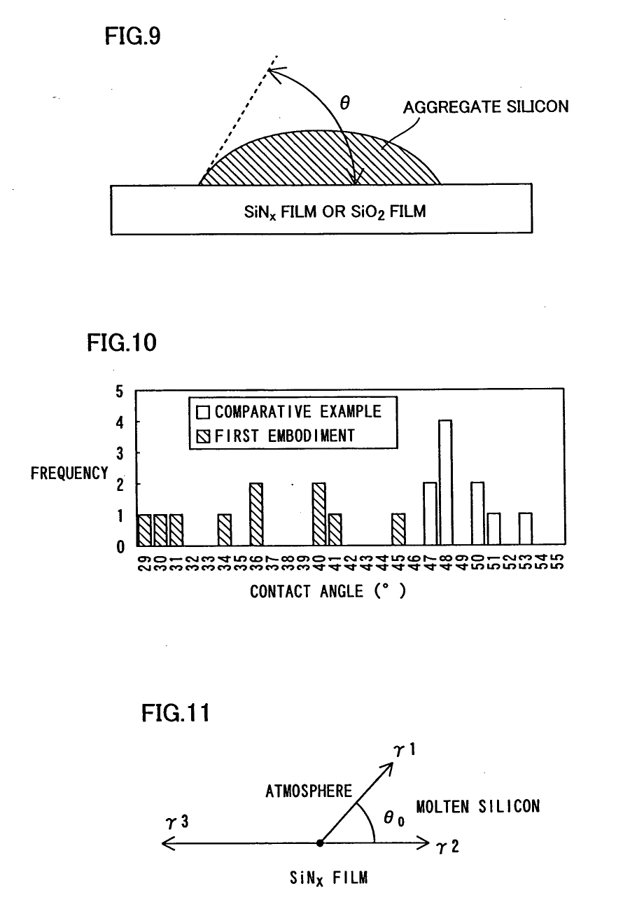

Another experiment of measuring contact angles of samples having the structures prepared according to the first embodiment and according to the comparative method shown in FIGS. 6 and 7 respectively with respect to bulked molten silicon is now described with reference to FIGS. 6 to 10. More specifically, agglomerate silicon formed by bulked molten silicon was observed with an SEM (scanning electron microscope) on the surface of a sample causing disappearance of a film structure due to agglomerating, as shown in FIG. 9. Contact angles θ (see FIG. 9) with respect to such agglomerate silicon were measured as to 10 samples having the structure prepared according to the first embodiment and 10 samples having the structure prepared according to the comparative method respectively, thereby measuring the contact angles of the samples with respect to molten silicon. FIG. 10 shows the results. The samples having the structure according to the first embodiment shown in FIG. 6, irradiated with YAG laser beams having outputs of at least 410 W to cause disappearance of film structures, were subjected to measurement of the contact angles. The samples having the structure prepared according to the comparative method shown in FIG. 7, irradiated YAG laser beams having outputs of at least 360 W to cause disappearance of film structures, were subjected to measurement of the contact angles.

Referring to FIG. 10, it is understood that the contact angles with respect to molten silicon are distributed in the range of not more than 45° in the samples having the structure according to the first embodiment shown in FIG. 6. It is also understood that the contact angles with respect to molten silicon are distributed in the range of at least 47° in the samples having the structure according to the comparative method shown in FIG. 7. From the results shown in FIGS. 7 and 8, it has been confirmed that molten silicon is hardly bulked when an SiNₓ film having a contact angle of not more than 45° with respect to molten silicon is formed to be in contact with the lower surface of an amorphous silicon film.

Table 1 shows contact angles of various materials having ordinary crystal composition ratios with respect to molten silicon.

TABLE 1

| Material | Contact Angle |
|---|---|
| SiC(1:1) | about 40° |
| Si₃N₄ | about 50° |
| SiO₂ | about 90° |
| BN(1:1) | about 150° |
| Graphite | about 150° |

It is understood from Table 1 that an SiC film having an ordinary crystal composition ratio exhibits a contact angle of not more than 45° with respect to molten silicon. When an SiC film is formed to be in contact with the lower surface of an amorphous silicon film, therefore, molten silicon can be hardly bulked due to the contact angle of not more than 45° with respect to molten silicon. It is also understood that a silicon nitride film (SiN film) having an ordinary crystal composition ratio (Si₃N₄) exhibits a contact angle (50°) larger than 45° with respect to molten silicon.

Still another experiment made for investigating conditions for forming an SiNₓ film suitable for reducing a contact angle with respect to molten silicon to not more than 45° is described with reference to FIGS. 6 and 11 to 13. In general, silicon nitride (SiN) prepared by plasma CVD or the like is notated as SiNₓ. Such silicon nitride prepared by plasma CVD or the like may have various composition ratios other than Si₃N₄, and includes that containing several % of hydrogen. The contact angle of such an SiNₓ film prepared by plasma CVD or the like with respect to molten silicon varies with the composition ratio or the hydrogen content of the SiNₓ film. Further, the composition ratio or the hydrogen content of the SiNₓ film varies with the conditions for forming the SiNₓ film.

Two types of samples Nos. 1 and 2 having structures similar to that prepared according to the first embodiment shown in FIG. 6 were prepared under different conditions (plasma CVD conditions) for forming SiNₓ films. Conditions for forming films other than the SiNₓ films were similar to those according to the aforementioned first embodiment. Contact angles of the SiNₓ films with respect to molten silicon were measured by melting amorphous silicon layers formed on the SiNₓ films by applying YAG laser beams and thereafter measuring contact angles of agglomerate silicon with respect to the SiNₓ films. The results of the measurement are now described.

First, the SiNₓ film of the sample No. 1 was prepared under plasma CVD conditions shown in Table 2.

TABLE 2

| Substrate Temperature | 400° C. |
|---|---|
| Pressure | 700 Pa |
| Flow Ratio | 1:1:50 |
| (SiH₄:NH₃:N₂) | |
| Power Density | 1.4 W/cm² |

The SiNₓ film of the sample No. 1 prepared under the conditions shown in Table 2 exhibited a contact angle of at least 45° with respect to molten silicon.

Then, the SiNₓ film of the sample No. 2 was prepared under plasma CVD conditions shown in Table 3.

TABLE 3

| | |
|---|---|
| Substrate Temperature | 400° C.˜450° C. |
| Pressure | 700 Pa |
| Flow Ratio | 2:1:100˜2:2:100 |
| (SiH₄:NH₃:N₂) | |
| Power Density | 2 W/cm² |

The SiNₓ film of the sample No. 2 prepared under the 10 conditions shown in Table 3 exhibited a contact angle of about 30° to about 45° with respect to molten silicon.

It has been understood from the aforementioned results of measurement of the samples Nos. 1 and 2 that the plasma CVD conditions for the SiNₓ film of the sample No. 2, i.e., the substrate temperature of 400° C. to 450° C., the pressure of 700 Pa, the flow ratios of SiH₄, NH₃ and N₂ of 2:1:100 to 2:2:100 and the power density of 2 W/cm² are preferable for reducing the contact angle of the SiNₓ film with respect to molten silicon to not more than 45°. Under the plasma CVD conditions for the SiNₓ film of the sample No. 2, the flow ratio of ammonia gas as well as the power density are increased as compared with the plasma CVD conditions for the SiNₓ film of the sample No. 1. Also when the contact angle of the SiNₓ film with respect to molten silicon exceeds 45° due to preparation under the conditions shown in Table 2 as in the sample No. 2, it is possible to reduce the contact angle to not more than 45° by forming roughness on the surface of the SiNₓ film coming into contact with molten silicon. The principle thereof is now described.

Referring to FIG. 11, it is assumed that γ1, γ2 and γ3 represent surface tension acting between molten silicon and an atmosphere, that acting between the molten silicon and an SiNₓ film and that acting between the SiNₓ film and the atmosphere respectively. It is also assumed that θ₀ represents the contact angle between the molten silicon and the SiNₓ film having no roughness on its surface (having a flat surface). In this case, the relation between the surface tension values γ1, γ2 and γ3 and the contact angle θ₀ is expressed as follows:

γ1·cos θ₀=(γ3−γ2) (1)

The above equation (1) can be transformed into the following equation (2):

cos θ₀=(γ3−γ2)/γ1 (2)

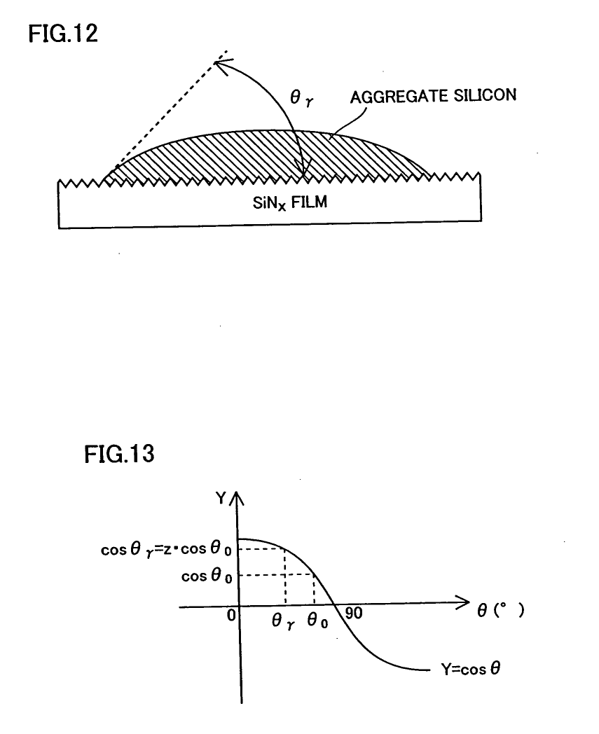

When roughness is formed on the surface of the SiNₓ film as shown in FIG. 12, the surface area of the SiNₓ film is so increased that the surface tension γ2 acting between the molten silicon and the SiNₓ film and the surface tension γ3 acting between the SiNₓ film and the atmosphere are also increased in proportion thereto. Assuming that roughness is so formed on the surface of the SiNₓ film that the surface area of the SiNₓ film is z times (z>1) that in the state having a flat surface, for example, the surface tension γ2 and the surface tension γ3 are also increased to z times. Assuming that θ_{γ} represents the contact angle of the SiNₓ film having the irregular surface with respect to molten silicon as shown in FIG. 12, therefore, the relation between the surface tension values γ1, γ2 and γ3 and the contact angle θ_{γ} can be expressed as follows from the above equation (2):

cos θ_{γ}=(z·γ3−z·γ2)/γ1=z((γ3−γ2)/γ1 (3)

From the above equations (2) and (3), the relation between the contact angle θ₀ of the SiNₓ film having a flat surface with respect to molten silicon and the contact angle θ_{γ} of the SiNₓ film having an irregular surface with respect to molten angle can be expressed as follows:

cos θ_{γ}=z·cos θ₀ (4)

From the above equation (4), the relation between the contact angles θ₀ and θ_{γ} can be expressed as shown in FIG. 13. It is understood from FIG. 13 that the contact angle θ_{γ} of the SiNₓ film having the irregular surface is smaller than the contact angle θ₀ of that having a flat surface. When an SiNₓ film having a flat surface exhibits a contact angle of less than 90° with respect to molten silicon, therefore, the contact angle with respect to molten silicon can conceivably be reduced by forming roughness on the surface of the SiNₓ film.

Roughness can be formed on the surface of the SiNₓ film by etching or the like. For example, it is possible to form roughness on the surface of the SiNₓ film for reducing the contact angle with respect to molten silicon by etching this surface under etching conditions shown in Table 4.

TABLE 4
Etching Conditions

| | |
|---|---|
| Substrate Temperature | 15° C.˜30° C. |
| Pressure | 7 Pa˜25 Pa |
| Flow Ratio | 1:5˜1:10 |
| (NF₃:Ar) | |
| Power Density | 1 W/cm²˜2 W/cm² |

According to the first embodiment, crystallization is performed by irradiating a fundamental wave of a continuous-wave YAG laser beam as hereinabove described so that the laser output can be increased as compared with a case of employing a harmonic, whereby the productivity (throughput) can be improved.

In the first embodiment, the fundamental wave of the continuous-wave YAG laser beam is hardly absorbed by the amorphous silicon film 6 but easily absorbed by the absorption film 3 of Mo, whereby the absorption film 3 can efficiently absorb the laser beam. Thus, the absorption film 3 can be so efficiently heated as to further efficiently crystallize the amorphous silicon film 6.

According to the first embodiment, further, the amorphous silicon film 6 is indirectly heated through the heat generated in the absorption film 3 irradiated with the continuous-wave YAG laser beam 100 so that dispersion of the heat conducted from the absorption film 3 to the amorphous silicon film 6 can be relaxed also when the continuous-wave YAG laser beam 100 applied to the absorption film 3 is dispersed to some extent. Thus, gigantic crystal grains or a single crystal can be formed without reducing the yield.

According to the first embodiment, in addition, the absorption film 3 can be also employed as a black matrix (BM) of a pixel part of a liquid crystal display or an organic EL display or a substrate bias plate after crystallization of the amorphous silicon film 6, whereby steps of removing the absorption film 3 and newly forming a black matrix or a substrate bias plate can be omitted. Consequently, the fabrication process can be simplified.

(Second Embodiment)

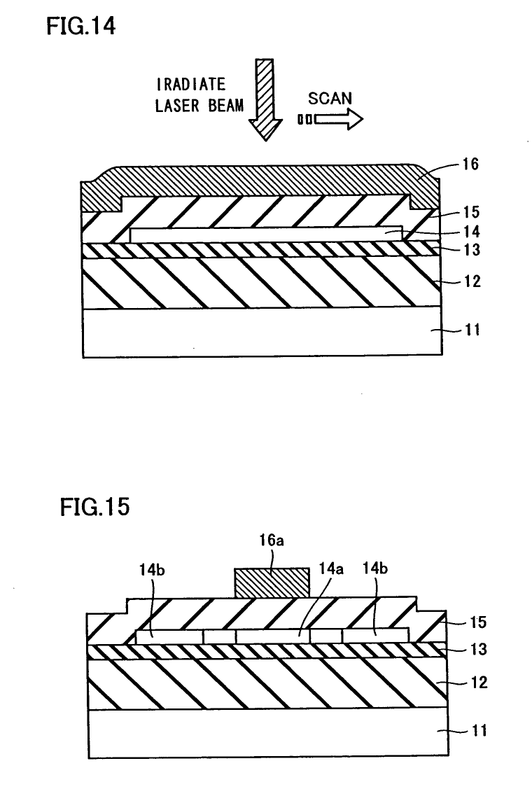

FIGS. 14 and 15 are sectional views for illustrating a method of fabricating a semiconductor device according to a second embodiment of the present invention. Referring to FIGS. 14 and 15, a laser beam is applied from above in the second embodiment dissimilarly to the aforementioned first embodiment.

As shown in FIG. 14, an SiO₂ film (silicon oxide film) 12 is formed on a glass substrate 11 by low-pressure CVD with a thickness of about 300 nm. This silicon oxide film 12 serves as a buffer layer for relaxing heat transfer to the glass substrate 11. Thereafter an SiNₓ film 13 is formed on the silicon oxide film 12 by plasma CVD with a thickness of about 20 nm. The SiNₓ film 13 has a contact angle of not more than 45°, smaller than that of the SiO₂ film 12, with respect to molten silicon. The SiNₓ film 13 is an example of the “first film” in the present invention. Thereafter an amorphous silicon film 14 is formed on the SiNₓ film 13 by low-pressure CVD with a thickness of about 50 nm. The amorphous silicon film 14 is an example of the “silicon layer” in the present invention. Thereafter the amorphous silicon film 14 is patterned into a prescribed shape.

Then, a gate insulator film 15 of SiO₂ is formed to cover the amorphous silicon film 14.l An absorption film 16 of Mo is formed on a prescribed region of the gate insulator film 15 by sputtering with a thickness of about 50 nm. Thereafter a fundamental wave of a continuous-wave YAG laser beam is applied from above the glass substrate 1, thereby crystallizing the amorphous silicon film 14 into a crystallized silicon film 14a under conditions of a laser output of about 400 W and a scanning rate of about 1 m/s.

Then, the absorption film 16 is patterned thereby forming a gate electrode 16a as shown in FIG. 15. The gate electrode 16a is employed as a mask for implanting an impurity into the crystallized silicon film 14a, thereby forming a pair of source/drain regions 14b having an LDD structure. In order to activate the implanted impurity, the continuous-wave YAG laser beam is applied similarly to the case of crystallization. Thus, a polycrystalline silicon TFT consisting of the pair of source/drain regions 14b, the gate insulator film 15 and the gate electrode 16a is formed according to the second embodiment.

According to the second embodiment, as hereinabove described, the buffer layer consisting of the SiO₂ film 12 is formed between the SiNₓ film 13 and the glass substrate 11 with the large thickness of about 300 nm, whereby it is possible to inhibit the glass substrate 11 from cracking or distortion resulting from a thermal shock with the buffer layer while inhibiting molten silicon from agglomerating with the SiNₓ film 13.

According to the second embodiment, further, the absorption film 16 can be utilized as the gate electrode 16a as hereinabove described, whereby steps of removing the absorption film 16 and newly forming a gate electrode can be omitted.

According to the second embodiment, in addition, the amorphous silicon film 14 is formed to be in contact with the upper surface of the SiNₓ film (silicon nitride film) 13 having the contact angle of not more than 45° with respect to molten silicon and thereafter molten to be crystallized similarly to the aforementioned first embodiment so that interfacial energy between molten silicon and the SiNₓ film 13 is reduced when the amorphous silicon film 14 is molten due to the SiNₓ film 13 having the small contact angle with respect to molten silicon, whereby wettability between the amorphous silicon film 14 and the SiNₓ film 13 can be improved. Thus, the amorphous silicon film 14 can be inhibited from agglomerating in a molten state.

The remaining effects of the second embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the SiNₓ film (silicon nitride film) 5 or 13 is employed as an exemplary film having a contact angle of not more than 45° with respect to molten silicon in each of the aforementioned embodiments, the present invention is not restricted to this but another film may alternatively be employed. For example, an insulator film of SiON or a semiconductor film of SiC is employable.

While the SiNₓ film (silicon nitride film) 5 or 13 is formed to be in contact with the lower surface of the amorphous film 6 or 14 in each of the aforementioned embodiments, the present invention is not restricted to this but the SiNₓ film (silicon nitride film) 5 or 13 may alternatively be formed to be in contact with the upper surface or both of the upper and lower surfaces of the amorphous film 6 or 14.

While the continuous-wave YAG laser beam is employed in each of the aforementioned embodiments, the present invention is not restricted to this but another laser beam may alternatively be employed so far as the same is an infrared laser beam. For example, a semiconductor laser beam, a glass laser beam or a YVO₄ laser beam may be employable. Further alternatively, a high-frequency wave, a microwave or lamplight capable of continuous heating may be employed in place of the continuous-wave laser beam. The continuous-wave laser beam, the high-frequency wave, the microwave, the lamplight etc. are generically referred to as “electromagnetic wave” in the present invention.

While the impurity in the source/drain regions 6b or 14b is activated with the continuous-wave YAG laser beam in each of the aforementioned embodiments, the present invention is not restricted to this but the impurity in the source/drain regions 6b or 14b may alternatively be activated by ELA (excimer laser annealing), RTA (rapid thermal annealing) or annealing at a relatively low temperature.

While the absorption film 3 or 16 consists of Mo in each of the aforementioned embodiments, the present invention is not restricted to this a film of a high melting point metal or an alloy or still another conductor film may alternatively be employed as the absorption film 3 or 16.

What is claimed is:

1. A method of fabricating a semiconductor device comprising steps of:
forming a silicon layer to be in contact with at least either the upper surface or the lower surface of a first film having a contact angle of not more than about 45° with respect to molten silicon; and
crystallizing said silicon layer after melting said silicon layer by heating said silicon layer with a continuously oscillated electromagnetic wave.

2. The method of fabricating a semiconductor device according to claim 1, wherein
said first film has a smaller contact angle with respect to molten silicon than a silicon oxide film.

3. The method of fabricating a semiconductor device according to claim 2, wherein
said first film includes at least either an SiNₓ film or an SiCN film having a contact angle of not more than about 45° with respect to molten silicon.

4. The method of fabricating a semiconductor device according to claim 2, wherein
said first film includes an SiC film.

5. The method of fabricating a semiconductor device according to claim 1, wherein
said step of crystallizing said silicon layer includes a step of forming an absorption film either above or under said silicon layer through an insulating layer, and a step of applying a continuous-wave laser beam to said absorption film thereby making said absorption film generate heat and crystallizing said silicon layer through generated said heat.

6. The method of fabricating a semiconductor device according to claim 5, wherein
said continuous-wave laser beam includes an infrared laser beam having a wavelength of at least about 0.75 μm and not more than about 2.0 μm.

7. The method of fabricating a semiconductor device according to claim 6, wherein
said continuous-wave laser beam includes a continuous-wave YAG laser beam.

8. The method of fabricating a semiconductor device according to claim 5, wherein
said absorption film consists of a material including Mo.

9. The method of fabricating a semiconductor device according to claim 5, further comprising a step of forming a gate electrode by patterning said absorption film after said step of forming said absorption film.

10. The method of fabricating a semiconductor device according to claim 5, wherein
said step of forming said absorption film includes a step of previously patterning said absorption film to be employable as a light-shielding film for a pixel part of a display.

11. The method of fabricating a semiconductor device according to claim 10, wherein
said step of previously patterning said absorption film to be employable as a light-shielding film for a pixel part of a display includes a step of patterning said absorption film in the form of a matrix.

12. The method of fabricating a semiconductor device according to claim 1, wherein
said step of crystallizing said silicon layer includes a step of heating said silicon layer with a fundamental wave of said continuous-wave laser beam.

13. The method of fabricating a semiconductor device according to claim 1, wherein
said step of forming said silicon layer includes a step of forming said silicon layer to be in contact with the upper surface of said first film,
said method of fabricating a semiconductor device further comprising a step of forming said first film on a substrate through a buffer layer for relaxing heat transfer to said substrate in advance of formation of said silicon layer.

14. The method of fabricating a semiconductor device according to claim 13, wherein
said buffer layer includes a silicon oxide film.

15. The method of fabricating a semiconductor device according to claim 1, further comprising steps of:
forming a source/drain region on said silicon layer by implanting an impurity into said silicon layer, and
activating said impurity in said source/drain region with said continuously oscillated electromagnetic wave.

16. The method of fabricating a semiconductor device according to claim 15, further including a step of forming a patterned gate electrode on said silicon layer in advance of said step of forming said source/drain region on said silicon layer.

17. The method of fabricating a semiconductor device according to claim 15, further including a step of applying a bias voltage between either said source or drain region of said silicon layer and said absorption film.

18. The method of fabricating a semiconductor device according to claim 1, further comprising a step of forming roughness on the surface of said first film to be formed with said silicon layer in advance of said step of forming said silicon layer.

19. The method of fabricating a semiconductor device according to claim 18, wherein
said step of forming said roughness includes a step of forming said roughness on the surface of said first film by etching the surface of said first film.

20. The method of fabricating a semiconductor device according to claim 1, wherein
said first film having said contact angle of not more than about 45° with respect to molten silicon is an SiNₓ film formed by plasma CVD.

21. The method of fabricating a semiconductor device according to claim 20, wherein
said SiNₓ film is formed by plasma CVD while setting the flow ratios of SiH₄ gas, NH₃ gas and N₂ gas to 2:1:100 to 2:2:100.
